(19) United States
(12) Patent Application Publication
(10) Pub. No.: US 2004/0264130 A1
(43) Pub. Date: Dec. 30, 2004

(54) Heat-dissipating device for flat display

(75) Inventor: Robert Liang, Taoyuan County (TW)

Correspondence Address: Havertock & Owens LLP, 162 North Wolfe Road, Sunnyvale, CA, 94086, US

(73) Assignee: Malico Inc

(21) Appl. No.: 10/866,538

(22) Filed: Jun. 10, 2004

(30) Foreign Application Priority Data
Jun. 30, 2003 (TW) 092212038

(51) Int. Cl. H05K 7/00; H05K 7/20

(52) U.S. Cl. 361/690

(57) ABSTRACT

A heat-dissipating device for a display is provided. The flat display includes a screen, a light source module, a control circuit board and a case with plural holes. The heat-dissipating device is made of heat-dissipating materials. The heat-dissipating device further includes a first heat-dissipating module and a second heat-dissipating module connected to the first heat-dissipating module. The heat-dissipating parts in the first heat-dissipating module form a plurality of spaces. And the convectional channel is formed by the first heat-dissipating module and the second heat-dissipating module. Finally the heat generated from light source module and the control circuit board is dissipated via the convectional channel and the plural of holes on the case.

### FIELD OF THE INVENTION

This invention relates to a heat-dissipating device for a flat display, and more particularly to a heat-dissipating device for the flat display screen of plasma display panel television (PDP TV), thin film transistor liquid crystal device television (TFT-LCD TV) or computer.

### BACKGROUND OF THE INVENTION

The light source of the flat display for the plasma display panel television (PDP TV) comes from a light source module included therein, which is similar to a daylight lamp. In addition, the light source of the flat display for the thin film transistor liquid crystal device television (TFT-LCD TV) or the computer is an additional backlight module, such as a direct type backlight module. Both the above light sources are the main heat sources of the displays. Now we instance the PDP-TV and the TFT-LCD TV as two different light modules to specify our point.

The light source module of PDP-TV display is formed by filling the gases of argon, neon, krypton and mercury vapor into two pieces of glasses. When a current is applied to the electrodes, the mercury atoms would be activated and the ultraviolet light (UV light) would be emitted thereform. And, the visible light would be generated after some fluorescent materials are hit by the UV light. During the discharge process, sixty percent of electric energy is transformed to UV light, and the remaining electric energy is transformed to heat energy. So the main heat source of PDP-TV display is the light source module. By using a 1 mm double-sided sheet, an aluminum film is attached to the glasses of PDP-TV display. Both the double-sided sheet and the aluminum film are heat-conducting materials and the heat is able to be dissipated thereform.

In addition, the main heat source of TFT-LCD TV display is its backlight module. The larger sized display of TFT-LCD TV needs more light to get a good performance, and, more heat would be come from the extra needed light consequently.

Nowadays, the common of PDP TV display and LCD TV display have a tendency to get larger, so that the temperature thereof is getting higher accordingly. All components of the display are usually covered with a case, since the small, compact and nice looking display is a trend. However, at the same time, the heat from the light source module and motherboard is not easy to be excluded from this airtight case. Lying in such high temperature causes the high molecular weight coating materials on light source module to decay quickly and the lifetime of PDP-TV display and LCD TV display are decreased accordingly.

To meet these challenges, some fans are added to the case just behind the display for extracting heat from it. Even so, it is known that there are still a lot of problems. First, the heat-dissipating efficiency of fans is not as well as expected, the average temperature is still higher than 75° C. Second, the integrated circuit (IC) of the fan will be easily damaged under the sustained high temperature environment so that the quality of TV would be unstable. The third problem is the annoying noise coming from the fans, and this substantially decreases the glamour of the product. Here we cite several common products with fans for dissipating heat. Please refer to FIG. 1A, which is a lateral view of the flat display for either a PDP-TV or a LCD-TV in prior art. As shown in FIG. 1A, the display 11 includes the screen 111, the light source module 112, the control circuit board 113, and the fan 114 and the case 115. There are other instances of the conventional displays, such as the display in FIG. 1B and FIG. 1C. Please refer to FIG. 1B and FIG. 1C, they are the rearviews of two conventional displays, wherein the fans 114 are arranged in different ways.

Therefore the ideal method is to produce a heat-dissipating device without fans for the flat display of PDP TV and TFT-LCD TV. And, the product with longer lifespan, higher quality but no additional noises and electromagnetic waves (EMI) are desirous. At present, there are no more fans on the second version heat-dissipating device for the flat display. The backlight module of the display with a second version heat-dissipating device is connected to a control circuit board, which has a heat sink. And the distinctive feature of the second version heat-dissipating device is that its heat sink is exposed outside the case for increasing the heat dissipating efficiency. Please refer to FIG. 2A and FIG. 2B, which are the displays with the second version heat-dissipating devices. The display 21 includes the screen 211, the light source module 212, the heat-conducting silicon sheet 213, the control circuit board 214, the heat sink 215 and the case 216. However, there are still some disadvantages in prior art. For example, people may be scalded by the heat sink exposed outside the case. Whereas the light source module and the control circuit board are both considered as heat sources and they are always arranged nearby, the heat-dissipating efficiency are not so good.

The main object of the present invention is to provide an improved heat-dissipating device for the flat display. The advantages of present invention are better heat dissipating efficiency, better performance quality, longer lifespan and lower cost.

### SUMMARY OF THE INVENTION

As the above discussion, a heat-dissipating device for the flat display that overcomes the disadvantages described above is desirous.

In one respect of the present invention, a heat-dissipating device for a display is provided. The heat-dissipating device for a display having a light source module and a control circuit board includes a first heat-dissipating module and a second heat-dissipating module.

The first heat-dissipating module includes a first heat-dissipating part with a first surface and a second surface, wherein the first surface is connected to the light source module, and a second heat-dissipating part having a plurality of heat-dissipating components is connected to the second surface of the first heat-dissipating part, wherein a plurality of spaces are formed between the plurality of heat-dissipating components.

The second heat-dissipating module connected to the first heat-dissipating module includes a third heat-dissipating part with a third surface connected to the control circuit board, a fourth heat-dissipating part, and a fifth heat-dissipating part. And the fourth heat-dissipating part and the fifth heat-dissipating part are respectively connected to the third heat-dissipating part and the first heat-dissipating part.

Preferably, the display further includes a screen and a case having a plurality of heat dissipation holes, and is one of a plasma display and a liquid crystal display.

Preferably, the heat-dissipating module is made of a heat-dissipating material. And the heat-dissipating material is one selected from a group consisting of a copper, aluminum, a heat pipe, a copper alloy, an aluminum alloy and a combination thereof.

Preferably, a convection channel is formed and enclosed by the fourth heat-dissipating part, the fifth heat-dissipating part, the control circuit board and the second heat-dissipating part.

Preferably, the air convection is formed through the plurality of heat dissipation holes, such that heat produced from the light source module and the control circuit board is dissipated.

Preferably, the first heat-dissipating part is one selected from a group consisting of a heat-dissipating fin, a heat sink, a heat-dissipating fin having a heat pipe therein, a heat sink having a heat pipe therein and a combination thereof.

Preferably, the second heat-dissipating part is one selected from a group consisting of a heat-dissipating fin, a heat sink, a heat-dissipating fin having a heat pipe therein, a heat sink having a heat pipe therein and a combination thereof.

Preferably, the plurality of heat-dissipating components are ones selected from a group consisting of a heat-dissipating fin, a heat sink, a heat-dissipating fin having a heat pipe therein, a heat sink having a heat pipe therein and a combination thereof.

Preferably, the third heat-dissipating part is one selected from a group consisting of a heat-dissipating fin, a heat sink, a heat-dissipating fin having a heat pipe therein, a heat sink having a heat pipe therein and a combination thereof.

Preferably, the fourth heat-dissipating part is one selected from a group consisting of a heat-dissipating fin, a heat sink, a heat-dissipating fin having a heat pipe therein, a heat sink having a heat pipe therein and a combination thereof.

Preferably, the fifth heat-dissipating part is one selected from a group consisting of a heat-dissipating fin, a heat sink, a heat-dissipating fin having a heat pipe therein, a heat sink having a heat pipe therein and a combination thereof.

Preferably, the first heat-dissipating module and the second heat-dissipating module are connected in a manner being one selected from a group consisting of an integrated formation, a soldering, a gluing, a fastening with a screw, a fastening with a rivet and a combination thereof.

Preferably, the first heat-dissipating part and the second heat-dissipating part are connected in a manner being one selected from a group consisting of an integrated formation, a soldering, a gluing, a fastening with a screw, a fastening with a rivet and a combination thereof.

Preferably, the third heat-dissipating part and the fourth heat-dissipating part are connected in a manner being one selected from a group consisting of an integrated formation, a soldering, a gluing, a fastening with a screw, a fastening with a rivet and a combination thereof.

Preferably, the third heat-dissipating part and the fifth heat part are connected in a manner being one selected from a group consisting of an integrated formation, a soldering, a gluing, a fastening with a screw, a fastening with a rivet and a combination thereof.

Preferably, the first heat-dissipating module and the light source module are connected in a manner being one selected from a group consisting of a soldering, a gluing, a fastening with a screw, a fastening with a rivet and a combination thereof.

Preferably, the second heat-dissipating module and the control circuit board are connected in a manner being one selected from a group consisting of a soldering, a gluing, a fastening with a screw, a fastening with a rivet and a combination thereof.

Preferably, the light source module is a light emitting module of a plasma display.

Preferably, the light source module is a backlight module of a liquid crystal display.

Preferably, the display is a flat display.

In accordance to another respect of the present invention, a heat-dissipating device for a display having a light source module and a control circuit board is provided. The heat-dissipating device includes a first heat-dissipating part connected to the light source module, a second heat-dissipating part connected to the control circuit board, a third heat-dissipating part, and a forth heat-dissipating part. And the third heat-dissipating part and the forth heat-dissipating part are respectively connected to the second heat-dissipating part and the first heat-dissipating part.

In accordance to another respect of the present invention, a heat-dissipating device for a display is provided. The heat-dissipating device for a display having a light source module and a control circuit board includes a first heat-dissipating part and a second heat-dissipating part. The two heat-dissipating part are respectively connected to the light source module and the control circuit board. Therefore a space enclosed by the first heat-dissipating part, the light source module, the second heat-dissipating part and the control circuit board is formed.

The above contents and advantages of the present invention will become more readily apparent to those ordinarily skilled in the art after reviewing the following detailed descriptions and accompanying drawings, in which:

### BRIEF DESCRIPTION OF THE DRAWINGS

FIG. 1A is a lateral view showing a display using fans for heat-dissipating in the prior art;

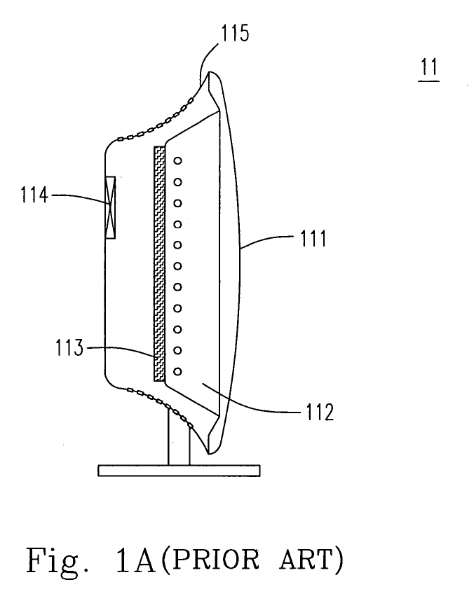

FIG. 1B is a rearview showing a display using fans for heat-dissipating in the prior art;

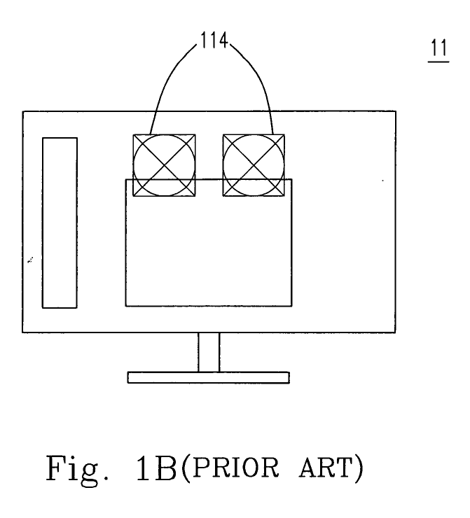

FIG. 1C is rearview showing another display using fans for heat-dissipating in the prior art;

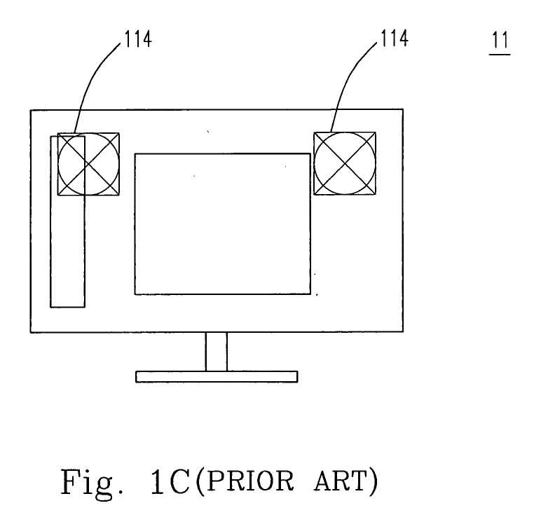

FIG. 2A is a perspective drawing showing a display using uncovered heat sinks for heat-dissipating in the prior art;

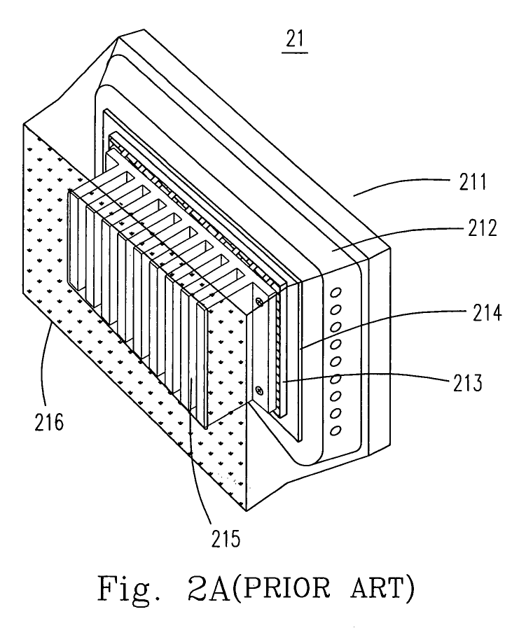

FIG. 2B is a vertical view showing a display using uncovered heat sinks for heat-dissipating in the prior art;

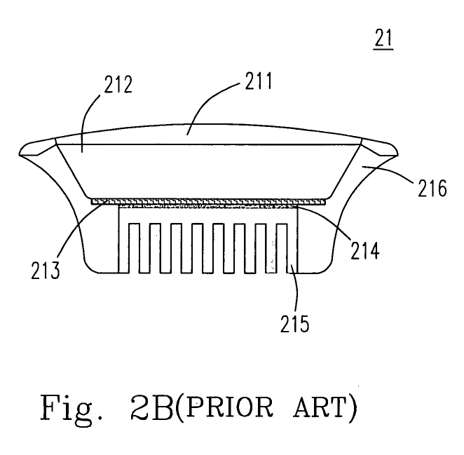

FIG. 3 is a perspective drawing showing a heat-dissipating device for a display according to a preferred embodiment of the present invention;

FIG. 4 is a top view showing a heat-dissipating device for a display according to a preferred embodiment of the present invention;

FIG. 5A is a structural schematic view showing the backside elements of a display according to a preferred embodiment of the present invention;

FIG. 5B is a schematic diagram showing a second heat dissipating part according to a preferred embodiment of the present invention;

FIG. 6A is a perspective drawing showing a heat-dissipating device for a display according to another preferred embodiment of the present invention;

FIG. 6B is a top view showing a heat-dissipating device for a display according to another preferred embodiment of the present invention; and

FIG. 6C is a top view showing a heat-dissipating device for a display according to another preferred embodiment of the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only; it is not intended to be exhaustive or to be limited to the precise form disclosed.

The present invention related to a better heat-dissipating device for the flat display. And the flat display can be part of a PDP-TV, a LCD TV or a computer. At present, a flat display device of PDP-TV or LCD TV will be used to interpret as following.

It is an object of the present invention to provide an enclosed heat sink to dissipate heat since the exposed heat sink used in prior art has a concern of burning people. The heat sinks, which are separately connected to an aluminum board of the light source module of the PDP-TV display or to a metal board connected to the backlight module of the LCD TV display, in present invention not only increase the area for heat dissipating but also produce the plurality of spaces able to convection. Furthermore, a convectional channel is formed by the plurality of spaces and plenty holes on the case. According to thermodynamics, the heat would be dissipated out of the display by the air convection.

It is another object of present invention to increase the heat-dissipating efficiency by separating the control circuit board from the light source module. The control circuit board is no longer connected to either an aluminum board of the light source module of PDP-TV display or to a metal board connected to the backlight module of the LCD TV display. These two elements are separated by the heat sinks or heat-dissipating module in the present invention.

There are many ways to lift the control circuit board away from the light source module. It can be accomplished by screwing the control circuit board to the metal board. And then the metal board is fastened to the heat sinks directly.

Or it can be done by connecting the control circuit board to a ∩-shape metal board and connecting the light source module to a metal board respectably. Then the two metal boards are fastened together with screws.

Or it can be done by connecting the light source module to a metal board, and being levitated over another metal board by a long screw. Then the control circuit board is screwed to the levitated board.

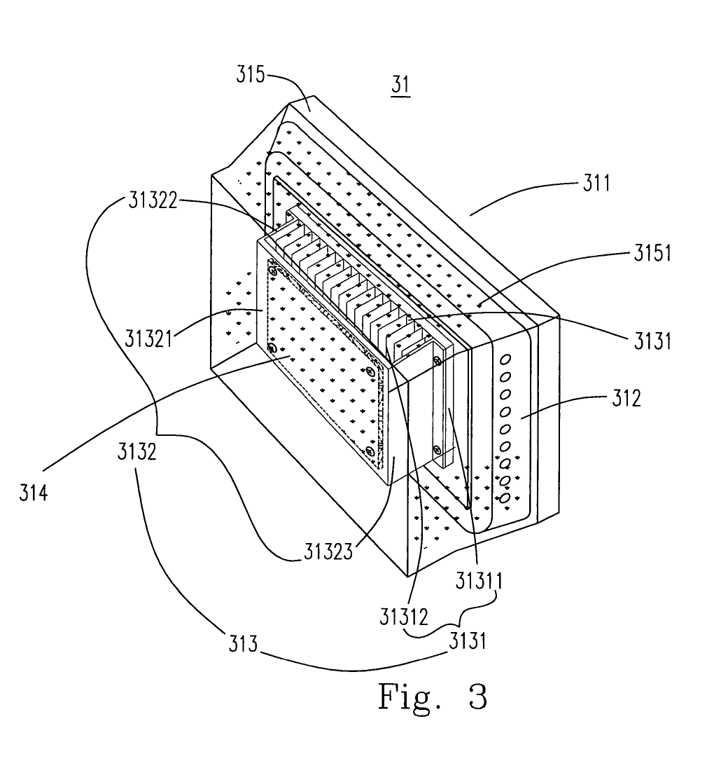

Please refer to FIG. 3, which is a perspective drawing showing a heat-dissipating device for a display according to a preferred embodiment of the present invention. The flat display device 31 is selected from the PDP-TV display or the LCD TV display. This flat display device 31 includes a screen 311, a light source module 312, a heat-dissipating device 313, a control circuit board 314 connected to the inner side of heat-dissipating device 313, and a case 315.

The heat-dissipating device 313 includes a first heat-dissipating module 3131 and a second heat-dissipating module 3132. The first heat-dissipating module 3131 includes a first heat-dissipating part 31311 and a second heat-dissipating part 31312. The second heat-dissipating module 3132 includes a third heat-dissipating part 31321, a fourth heat-dissipating part 31322, and a fifth heat-dissipating part 31323.

The fourth heat-dissipating part 31322 and the fifth heat-dissipating part 31323 are respectively connected to the both sides of the control circuit board 314 and the both sides of the first heat-dissipating part 31311.

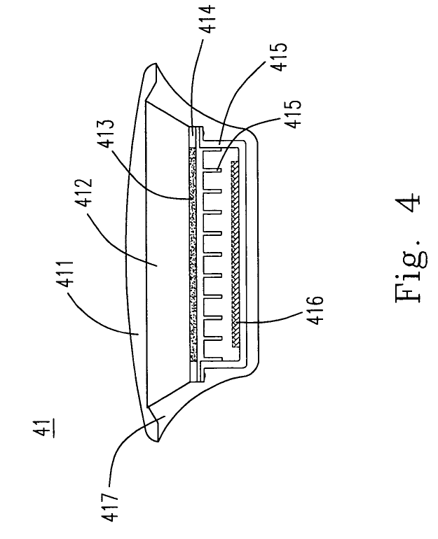

And a convectional channel is formed by the fourth heat-dissipating part 31322, the fifth heat-dissipating part 31323, the control circuit board 314 and the plurality of spaces between second heat-dissipating part 31312. Please refer to FIG. 4 for a better understating of the conventional channel. And the hot air flow is arisen from plural holes on the case 3151 and the convention channel. So the heat generated from the light source module 312 and the control circuit module 314 is dissipated.

The heat-dissipating device 313 is made of a heat-dissipating material. And the heat-dissipating material is one selected from a group consisting of a copper, aluminum, a heat pipe, a copper alloy, an aluminum alloy and a combination thereof.

And the elements of heat-dissipating device 313, which includes the first heat-dissipating part 31311, the second heat-dissipating part 31312, the third heat-dissipating part 31321, the fourth heat-dissipating part 31322, and the fifth heat-dissipating part 31323, are selected from a group consisting of a heat-dissipating fin, a heat sink, a heat-dissipating fin having a heat pipe therein, a heat sink having a heat pipe therein and a combination thereof.

The first heat-dissipating module 3131 and the second heat-dissipating module 3132 are connected in a manner being one selected from a group consisting of an integrated formation, a soldering, a gluing, a fastening with a screw, a fastening with a rivet and a combination thereof.

The first heat-dissipating part 31311 and the second heat-dissipating part 31312 are connected in a manner being one selected from a group consisting of an integrated formation, a soldering, a gluing, a fastening with a screw, a fastening with a rivet and a combination thereof.

The third heat-dissipating part 31321 and the fourth heat-dissipating part 31322 are connected in a manner being one selected from a group consisting of an integrated formation, a soldering, a gluing, a fastening with a screw, a fastening with a rivet and a combination thereof.

The third heat-dissipating part 31321 and the fifth heat-dissipating part 31323 are connected in a manner being one selected from a group consisting of an integrated formation, a soldering, a gluing, a fastening with a screw, a fastening with a rivet and a combination thereof.

The first heat-dissipating module 3131 and the light source module 312 are connected in a manner being one selected from a group consisting of a soldering, a gluing, a fastening with a screw, a fastening with a rivet and a combination thereof.

The second heat-dissipating module 3132 and the control circuit board 314 are connected in a manner being one selected from a group consisting of a soldering, a gluing, a fastening with a screw, a fastening with a rivet and a combination thereof.

Please refer to FIG. 4, which is a top view showing a heat-dissipating device for a display according to a preferred embodiment of the present invention. The flat display device 41 includes a screen 411, a light source module 412, an adhesive heat-conducting silicon sheet 413 connected to the back side of the light source module 412, a heat-dissipating module 415, a control circuit board 416, a holder 414 for the heat-dissipating module 415 and the control circuit board 414 and a case 417.

The heat-dissipating module 415 and control circuit board 416 are fasten to the light source module 412 in a manner being one selected from a group consisting of a soldering, a gluing, a fastening with a screw, a fastening with a rivet and a combination thereof.

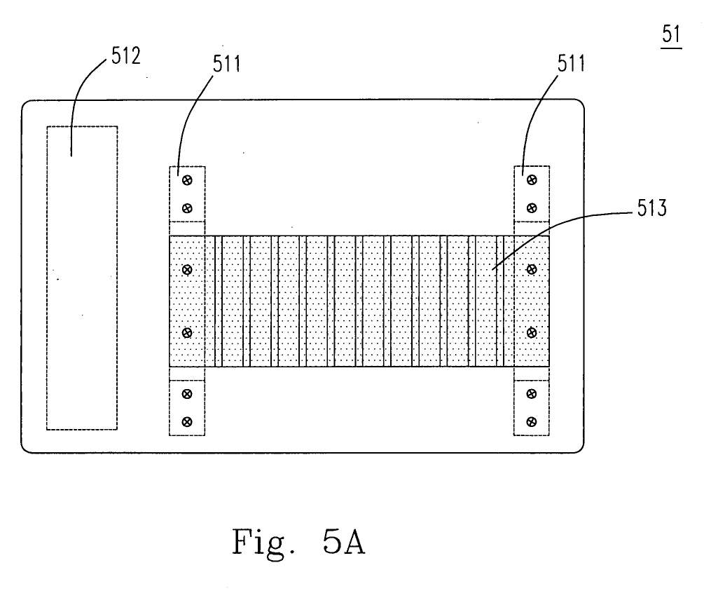

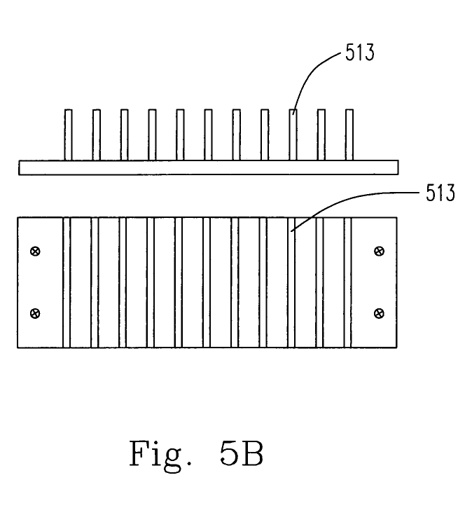

Please refer to FIG. 5A, which is a structural schematic view showing the backside elements for a display 51 according to a preferred embodiment of the present invention. FIG. 5A shows the detailed structure of the holders 511, which support the heat-dissipating module, the control circuit board, a transformer 512 and the second heat-dissipating part 513.

FIG. 5B is a side view showing a second heat dissipating part 513 in side viewing.

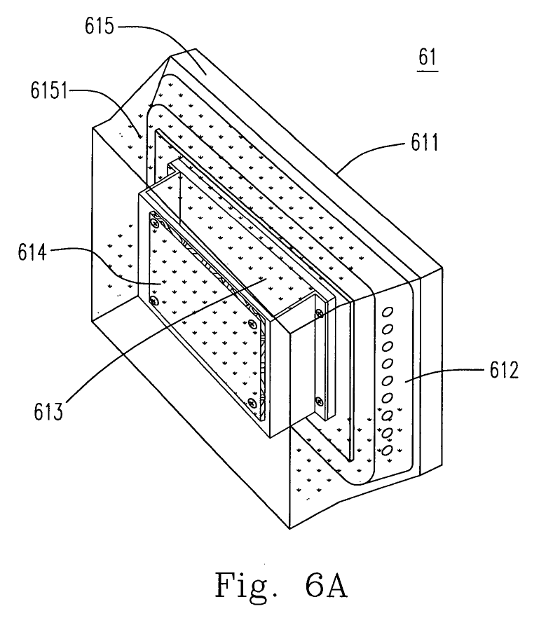

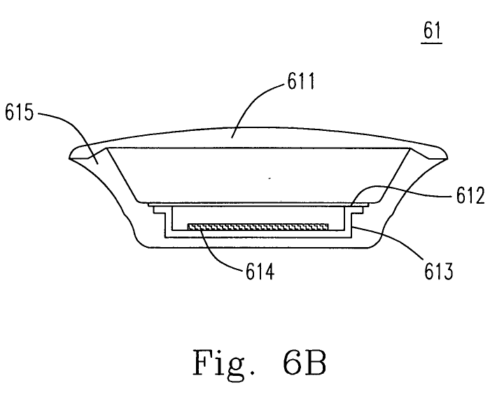

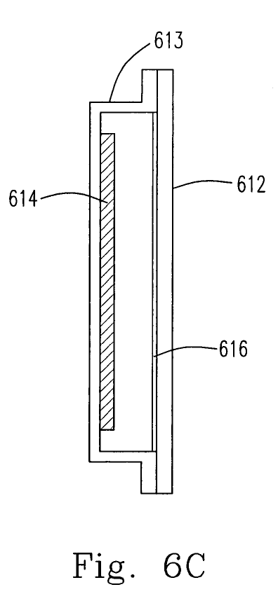

Please refer to FIG. 6, which is a display according to another preferred embodiment of the present invention. Please refer to FIG. 3A and FIG. 3B, wherein the second dissipating module 3132 is removed from FIG. 6.

Please refer to FIG. 6A, which is a perspective drawing showing a heat-dissipating device for a display according to another preferred embodiment of the present invention. The flat display 61 is one selected from a PDP-TV display, a LCD TV display or a computer display. This flat display 61 includes a screen 611, a light source module 612, a heat-dissipating device 613, a control circuit board 614 connected to the inner side of heat-dissipating module 613, and a case 615 with plural holes 6151.

Please refer to FIG. 6B, which is a top view of the heat-dissipating device in FIG. 6A.

Please refer to FIG. 6C, which is a top view of the heat-dissipating device in FIG. 6A. A heat-conducting silicon sheet 616 is attached to the backside of light source module 612. Therefore the convention channel is form by the heat-dissipating module 613 and the heat-conducting silicon sheet 616, which is attached to the backside of light source module 612. The heat is dissipated via the convectional channel and the plural holes 6151 on the case 615. (Please refer to FIG. 6B.)

And the heat generated from control circuit board would be dissipated due to the heat conduction effect and the heat radiation effect of the heat-dissipating module 613. By the both ways described above, the heat would be dissipated and the temperature inside the display would be decreased. Therefore, the relevant cost of the product can be economized.

In conclusion, the present invention separates the light source module from the control circuit board, both are the main heat sources for a flat display, which is one selected from a PDP-TV display, a LCD TV display and a computer display. Moreover, the light source module and the control circuit board are connected to heat-conduction materials, which are selected from a group consisting of a copper, aluminum, a heat pipe, a copper alloy, an aluminum alloy and a combination thereof, for better heat dissipating. Especially, the air convection is available through plural holes on the case and the convectional channel formed by the heat-dissipating module.

A safer and more efficient heat-dissipating module is provided in the present invention. Since the high temperature sinks are no longer exposed out of the case as described in prior art, the users now are free from burning their hands accidentally. And since the heat sources in the present invention are separated from each other, the heat-dissipating efficiently is improved. Therefore the present invention does have the novelty, progressiveness and utility.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims, which are to be accorded with the broadest interpretation so as to encompass all such modifications and similar structures.

What is claimed is:

1. A heat-dissipating device for a display having a light source module and a control circuit board, comprising:
a first heat-dissipating module comprising:
a first heat-dissipating part with a first surface and a second surface, wherein said first surface is connected to said light source module; and a second heat-dissipating part having a plurality of heat-dissipating components connected to said second surface of said first heat-dissipating part, wherein a plurality of spaces are formed in said plurality of heat-dissipating components; and
a second heat-dissipating module connected to said first heat-dissipating module, comprising:
a third heat-dissipating part with a third surface connected to said control circuit board;
a fourth heat-dissipating part; and
a fifth heat-dissipating part, wherein said fourth heat-dissipating part and said fifth heat-dissipating part are respectively connected to said third heat-dissipating part and said first heat-dissipating part.

2. The heat-dissipating device according to claim 1, wherein said display further includes a screen and a casing having a plurality of heat dissipation holes, and is one of a plasma display and a liquid crystal display.

3. The heat-dissipating device according to claim 1, said heat-dissipating module is made of a heat-dissipating material.

4. The heat-dissipating device according to claim 3, wherein said heat-dissipating material is one selected from a group consisting of a copper, an aluminum, a heat pipe, a copper alloy, an aluminum alloy and a combination thereof.

5. The heat-dissipating device according to claim 1, wherein a convection channel is formed and enclosed by said fourth heat-dissipating part, said fifth heat-dissipating part, said control circuit board and said second heat-dissipating part.

6. The heat-dissipating device according to claim 5, wherein an air convection is formed through said plurality of heat dissipation holes, such that heat produced from said light source module and said control circuit board is dissipated.

7. The heat-dissipating device according to claim 1, wherein said first heat-dissipating part is one selected from a group consisting of a heat-dissipating fin, a heat sink, a heat-dissipating fin having a heat pipe therein, a heat sink having a heat pipe therein and a combination thereof.

8. The heat-dissipating device according to claim 1, wherein said second heat-dissipating part is one selected from a group consisting of a heat-dissipating fin, a heat sink, a heat-dissipating fin having a heat pipe therein, a heat sink having a heat pipe therein and a combination thereof.

9. The heat-dissipating device according to claim 1, wherein said plurality of heat-dissipating components are ones selected from a group consisting of a heat-dissipating fin, a heat sink, a heat-dissipating fin having a heat pipe therein, a heat sink having a heat pipe therein and a combination thereof.

10. The heat-dissipating device according to claim 1, wherein said third heat-dissipating part is one selected from a group consisting of a heat-dissipating fin, a heat sink, a heat-dissipating fin having a heat pipe therein, a heat sink having a heat pipe therein and a combination thereof.

11. The heat-dissipating device according to claim 1, wherein said fourth heat-dissipating part is one selected from a group consisting of a heat-dissipating fin, a heat sink, a heat-dissipating fin having a heat pipe therein, a heat sink having a heat pipe therein and a combination thereof.

12. The heat-dissipating device according to claim 1, wherein said fifth heat-dissipating part is one selected from a group consisting of a heat-dissipating fin, a heat sink, a heat-dissipating fin having a heat pipe therein, a heat sink having a heat pipe therein and a combination thereof.

13. The heat-dissipating device according to claim 1, wherein said first heat-dissipating module and said second heat-dissipating module are connected in a manner being one selected from a group consisting of an integrated formation, a soldering, a gluing, a fastening with a screw, a fastening with a rivet and a combination thereof.

14. The heat-dissipating device according to claim 1, wherein said first heat-dissipating part and said second heat-dissipating part are connected in a manner being one selected from a group consisting of an integrated formation, a soldering, a gluing, a fastening with a screw, a fastening with a rivet and a combination thereof.

15. The heat-dissipating device according to claim 1, wherein said third heat-dissipating part and said fourth heat-dissipating part are connected in a manner being one selected from a group consisting of an integrated formation, a soldering, a gluing, a fastening with a screw, a fastening with a rivet and a combination thereof.

16. The heat-dissipating device according to claim 1, wherein said third heat-dissipating part and said fifth heat part are connected in a manner being one selected from a group consisting of an integrated formation, a soldering, a gluing, a fastening with a screw, a fastening with a rivet and a combination thereof.

17. The heat-dissipating device according to claim 1, wherein said first heat-dissipating module and said light source module are connected in a manner being one selected from a group consisting of a soldering, a gluing, a fastening with a screw, a fastening with a rivet and a combination thereof.

18. The heat-dissipating device according to claim 1, wherein said second heat-dissipating module and said control circuit board are connected in a manner being one selected from a group consisting of a soldering, a gluing, a fastening with a screw, a fastening with a rivet and a combination thereof.

19. The heat-dissipating device according to claim 1, wherein said light source module is a light emitting module of a plasma display.

20. The heat-dissipating device according to claim 1, wherein said light source module is a backlight module of a liquid crystal display.

21. The heat-dissipating device according to claim 1, wherein said display is a flat display.

22. A heat-dissipating device for a display having a light source module and a control circuit board, comprising:
a first heat-dissipating part connected to said light source module;
a second heat-dissipating part connected to said control circuit board;
a third heat-dissipating part; and
a forth heat-dissipating part,
wherein said third heat-dissipating part and said forth heat-dissipating part are respectively connected to said second heat-dissipating part and said first heat-dissipating part.

23. A heat-dissipating device for a display having a light source module and a control circuit board, comprising:
a first heat-dissipating part connected to said light source module and said control circuit board; and
a second heat-dissipating part connected to said light source module and said control circuit board,
wherein a space enclosed by said first heat-dissipating part, said light source module, said second heat-dissipating part and said control circuit board is formed.
